(19) United States
(12) Patent Application Publication
(10) Pub. No.: US 2026/0143918 A1
(43) Pub. Date: May 21, 2026

(54) DISPLAY DEVICE INCLUDING DIFFERENT SUB-ELECTRODES AND METHOD FOR MANUFACTURING THE SAME

(71) Applicant: SAMSUNG DISPLAY CO., LTD., YONGIN-SI (KR)

(72) Inventors: Hyung Seok KIM, Yongin-si (KR); Hye Lim KANG, Yongin-si (KR); Woo Seok JEON, Yongin-si (KR); So Yeong JEONG, Yongin-si (KR); Yung Bin CHUNG, Yongin-si (KR)

(21) Appl. No.: 19/257,697

(22) Filed: Jul. 2, 2025

(30) Foreign Application Priority Data
Nov. 19, 2024 (KR) 10-2024-0165553

(51) Int. Cl. H10K 59/122; H10H 29/01; H10H 29/37; H10H 29/80; H10K 59/12; H10K 59/80; H10K 71/60; H10K 102/00; H10K 102/10

(52) U.S. Cl. CPC H10K 59/122; H10H 29/012; H10H 29/032; H10H 29/37; H10H 29/8323; H10K 59/1201; H10K 59/80524; H10K 71/60; H10K 2102/102; H10K 2102/103; H10K 2102/351

(57) ABSTRACT

Embodiments of the present disclosure provide a display device and a method to manufacture the display device. The method includes forming a first electrode on a substrate, forming a pixel-defining layer on the substrate, where the pixel-defining layer includes an opening that exposes at least a portion of an upper surface of the first electrode, forming a light-emitting layer on the upper surface of the first electrode, and forming a second electrode on the light-emitting layer and the pixel-defining layer using spatial atomic layer deposition (spatial ALD), where the second electrode includes a first sub-electrode and a second sub-electrode disposed on the first sub-electrode, and where the second electrode is formed in a deposition chamber.

### CROSS-REFERENCE TO RELATED APPLICATION

This non-provisional patent application claims priority under 35 U.S.C. § 119 to Korean Patent Application No. 10-2024-0165553 filed on Nov. 19, 2024 in the Korean Intellectual Property Office, the disclosure of which is incorporated by reference herein in its entirety.

### TECHNICAL FIELD

The present disclosure relates to a display device and, more particularly, to a display device including different sub-electrodes and a method for manufacturing the same.

### DISCUSSION OF THE RELATED ART

With the advancement of the information society, the demand for various types of display devices for displaying images has gained widespread demand. For example, these display device may include a flat panel display such as a liquid crystal display (LCD), a field-emission display (FED), or a light-emitting display. A light-emitting display may include an organic light-emitting display device including organic light-emitting elements, an inorganic light-emitting display device including inorganic light-emitting elements such as inorganic semiconductors, or a micro-light-emitting display device including micro light-emitting elements.

### SUMMARY

Embodiments of the present disclosure provide a method for manufacturing a display device, the method includes forming a first electrode on a substrate, and forming a pixel-defining layer on the substrate. The pixel-defining layer includes an opening that exposes at least a portion of an upper surface of the first electrode. The method further include forming a light-emitting layer on the upper surface of the first electrode, and forming a second electrode on the light-emitting layer and the pixel-defining layer using spatial atomic layer deposition. The second electrode includes a first sub-electrode and a second sub-electrode disposed on the first sub-electrode, and the first sub-electrode and the second sub-electrode are formed in a single deposition chamber.

The first sub-electrode and second sub-electrode may include different materials, and the second electrode may be formed within a single chamber.

The second electrode may be formed by supplying a first precursor into a first precursor adsorption space of the chamber to adsorb the first precursor onto the light-emitting layer and the pixel-defining layer, stopping the supply of the first precursor and moving the substrate to a first exhaust space in the chamber, and exhausting the first precursor from the first exhaust space. The second electrode may be formed by moving the substrate to a first purge gas supply space in the chamber and supplying a purge gas onto the adsorbed first precursor, moving the substrate to a second exhaust space in the chamber and exhausting the purge gas, moving the substrate to a first oxidant supply space in the chamber and forming the first sub-electrode by supplying an oxidant to oxidize the adsorbed first precursor, and moving the substrate to a third exhaust space in the chamber and exhausting the oxidant. The second electrode may be formed by moving the substrate to a second purge gas supply space in the chamber and supplying the purge gas onto the first sub-electrode, moving the substrate to a fourth exhaust space in the chamber and exhausting the purge gas, moving the substrate to a second precursor supply space in the chamber and supplying a second precursor into adsorb the second precursor onto the first sub-electrode, stopping the supply of the second precursor, moving the substrate to a fifth exhaust space in the chamber, and exhausting the second precursor in the fifth exhaust space. The second electrode may be formed by moving the substrate to a third purge gas supply space in the chamber and supplying the purge gas onto the adsorbed second precursor, moving the substrate to a sixth exhaust space in the chamber and exhausting the purge gas, moving the substrate to a second oxidant supply space in the chamber and forming the second sub-electrode by supplying the oxidant to oxidize the adsorbed second precursor, moving the substrate to a seventh exhaust space in the chamber and exhausting the oxidant, moving the substrate to a fourth purge gas supply space in the chamber and supplying the purge gas onto the second sub-electrode, and moving the substrate to an eighth exhaust space in the chamber and exhausting the purge gas.

In some cases, the second electrode may be formed by supplying a first precursor into the deposition chamber to adsorb the first precursor onto the light-emitting layer and the pixel-defining layer, exhausting an excess of the first precursor in the deposition chamber, supplying a purge gas onto the adsorbed first precursor in the deposition chamber, forming the first sub-electrode by supplying an oxidant to oxidize the adsorbed first precursor in the deposition chamber, supplying a second precursor into the deposition chamber to adsorb the second precursor onto the first sub-electrode, exhausting an excess of the second precursor in the deposition chamber, supplying the purge gas onto the adsorbed second precursor in the deposition chamber, forming the second sub-electrode by supplying the oxidant to oxidize the adsorbed second precursor, and exhausting an excess of the oxidant.

The second electrode may include at least one of indium oxide, zinc oxide, tin oxide, aluminum oxide, or gallium oxide. The first and second precursors may include at least one of indium, zinc, tin, aluminum, or gallium.

A thickness of the second electrode may range from 10 Å to 1,000 Å. In some cases, a spacer may be formed on the pixel-defining layer.

A first thickness of the second electrode measured from an upper surface of the pixel-defining layer may be within a range 90% to 100% of a second thickness of the second electrode measured from a side surfaces of the pixel-defining layer.

A ratio of a thickness of the first sub-electrode to a thickness of the second sub-electrode may be greater than or equal to 10:1.

Forming the second electrode further may include forming a third sub-electrode on the second sub-electrode, and forming a fourth sub-electrode on the third sub-electrode.

The first sub-electrode, second sub-electrode, third sub-electrode, or fourth sub-electrode may have a characteristic of crystallinity when having a thickness of 20 Å or greater. The crystallinity may correspond to at least one of the (222), (100), or (002) crystal orientation.

Embodiments of the present disclosure provide a display device including a substrate, a first electrode disposed on the substrate, and a pixel-defining layer disposed on the first electrode. The pixel-defining layer includes an opening that exposes at least a portion of an upper surface of the first electrode. The display device further includes a light-emitting layer disposed on the upper surface of the first electrode, and a second electrode disposed on the light-emitting layer and the pixel-defining layer. The second electrode includes a first sub-electrode and a second sub-electrode is disposed on the first sub-electrode, a thickness of the second electrode ranges from 10 Å to 1,000 Å, and a ratio of a thickness of the first sub-electrode to a thickness of the second sub-electrode is greater than or equal to 10:1.

The second electrode may further include a third sub-electrode disposed on the second sub-electrode and a fourth sub-electrode disposed on the third sub-electrode.

A first thickness of the second electrode measured from an upper surface of the pixel-defining layer may be within 90% to 100% of a second thickness of the second electrode measured from a side surface of the pixel-defining layer.

The second electrode may include at least one of indium oxide, zinc oxide, tin oxide, aluminum oxide, or gallium oxide.

The first sub-electrode, second sub-electrode, third sub-electrode, or fourth sub-electrode may have a characteristic of crystallinity when having a thickness of 20 Å or greater.

The crystallinity may correspond to at least one of the (222), (100), or (002) crystal orientation.

Embodiments of the present disclosure provide an electronic device including a processor, a memory having stored application programs for execution by the processor, and a display device including a display panel. The display panel includes a first electrode is disposed on the substrate, and a pixel-defining layer disposed on the first electrode. The pixel-defining layer includes an opening that exposes at least a portion of an upper surface of the first electrode. The display panel further includes a light-emitting layer disposed on the upper surface of the first electrode, and a second electrode disposed on the light-emitting layer and the pixel-defining layer. The second electrode includes a first sub-electrode and a second sub-electrode disposed on the first sub-electrode, a thickness of the second electrode ranges from 10 Å to 1,000 Å, and a ratio of a thickness of the first sub-electrode to a thickness of the second sub-electrode is greater than or equal to 10:1.

### BRIEF DESCRIPTION OF THE DRAWINGS

The above and other aspects and features of the present disclosure will become more apparent by describing in detail example embodiments thereof with reference to the attached drawings, in which:

FIG. 1 is a perspective view of a display device according to an embodiment of the present disclosure;

FIG. 2 is a cross-sectional view of a display panel according to an embodiment of the present disclosure. ;

FIG. 3 is an enlarged cross-sectional view of area A in FIG. 2;

FIG. 4 shows an example of cross-sectional images of wire grid polarizers with indium oxide deposited thereon using scanning electron microscope (SEM);

FIG. 5 is an enlarged cross-sectional view of area B in FIG. 2;

FIG. 6 is a flowchart illustrating a method for manufacturing a display device according to an embodiment of the present disclosure;

FIG. 7 is a cross-sectional view illustrating a substrate and a first electrode in step S100 of FIG. 6;

FIG. 8 is a cross-sectional view illustrating the substrate, the first electrode, and a pixel-defining layer in step S200 of FIG. 6;

FIG. 9 is a cross-sectional view illustrating the substrate, the first electrode, the pixel-defining layer, and a light-emitting layer in step S300 of FIG. 6;

FIG. 10 is a cross-sectional view illustrating a substrate, a first electrode, a pixel-defining layer, a light-emitting layer, and spacers according to an embodiment of the present disclosure;

FIG. 11 is a flowchart illustrating a method for manufacturing a second electrode according to an embodiment of the present disclosure;

FIG. 12 is a cross-sectional view of a spatial atomic layer deposition (ALD) chamber according to an embodiment of the present disclosure;

FIG. 13 is a cross-sectional view illustrating the substrate, the first electrode, the pixel-defining layer, the light-emitting layer, the spacers, and a first sub-electrode according to an embodiment of the present disclosure;

FIG. 14 is a cross-sectional view illustrating the substrate, the first electrode, the pixel-defining layer, the light-emitting layer, the spacers, the first sub-electrode, and a second sub-electrode according to an embodiment of the present disclosure;

FIG. 15 is an X-ray photoelectron spectroscopy (XPS) graph based on a first electrode fabrication embodiment;

FIG. 16 is an XPS graph based on a second electrode fabrication embodiment;

FIG. 17 is a graph showing the resistance based on the third electrode, fourth, and the fifth electrode fabrication embodiments;

FIG. 18 is an XPS depth profile graph based on a stacked fabrication embodiment; and

FIG. 19 is a diagram illustrating an electronic device according to an embodiment of the present invention.

### DETAILED DESCRIPTION

Features of the present invention, and the methods for manufacturing the display device is described in detail with reference to the embodiments and the accompanying drawings. However, the present invention is not necessarily limited to the embodiments disclosed below, but may be implemented in various different forms, and these embodiments are provided to make the disclosure of the present invention complete and to fully inform those skilled in the art of the invention of the scope of the invention.

As described herein, when elements or layers are referred to as “on” another element or layer, this includes cases where another layer or another element is interposed directly on or in the middle of the other element. The same reference numerals refer to the same components throughout the specification. The shapes, sizes, ratios, angles, numbers, etc. disclosed in the drawings are used for describing the embodiments, and therefore the present invention is not necessarily limited to the matters illustrated.

It will be understood that, although the terms “first,” “second,” etc. may be used herein to describe various elements, these elements should not be limited by these terms. These terms are used to distinguish one element from another element. For example, a first element discussed below could be termed a second element without departing from the teachings and spirit of the present disclosure. Similarly, the second element could also be termed the first element.

Each feature of the various embodiments of the present invention may be partially or entirely combined or combined with each other, and may be technically capable of various interconnections and operations. Each embodiment may be implemented independently of each other or may be implemented together in a related relationship. Embodiments of the present disclosure are described below with reference to the attached drawings.

Embodiments of the present disclosure provide a display device including a first electrode formed on a substrate, a pixel-defining layer including an emission region disposed on the first electrode, a light-emitting layer disposed on the first electrode within the emission region, and a second electrode uniformly covering the light-emitting layer and the pixel-defining layer. In some embodiments, the second electrode includes a multilayer structure formed by sequentially depositing a first sub-electrode of indium oxide (In₂O₃) and a second sub-electrode of zinc oxide (ZnO) using a spatial atomic layer deposition (ALD) method within a single chamber. forming the second electrode in a single chamber (e.g., a deposition chamber), embodiments of the present disclosure can reduce process complexity, minimize particle contamination, and improve manufacturing efficiency compared to conventional multi-chamber deposition processes.

In some aspects, the first sub-electrode is formed to have a greater thickness to ensure high electrical conductivity, while the second sub-electrode is formed to have a smaller thickness to enhance surface stability. By controlling the thickness ratio between the first and second sub-electrodes, the structure optimizes electrode performance such as combining low resistance from the In₂O₃ layer with uniform coverage provided by the ZnO layer, even over complex topographies (e.g., the complex surface features of the second electrode). Accordingly, the second electrode configuration enhances the electrical efficiency, reduces the thickness, and improves step coverage. According to the method for manufacturing a display device of the present disclosure, process time can be reduced by forming electrodes using a spatial ALD method. Additionally, electrodes with reduced thickness and improved step coverage can be provided.

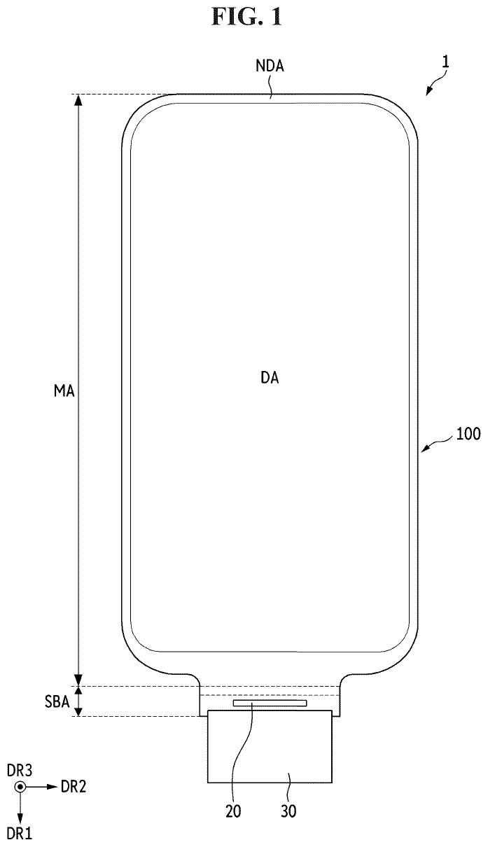

FIG. 1 is a plan view of a display device according to an embodiment of the present disclosure. The example shown includes a display device 1, display panel 100, a display driving circuit 20, and a circuit board 30.

Referring to FIG. 1, a display device 1 is a device that displays moving or still images and may be used as a display screen for various products, including portable electronic devices such as mobile phones, smartphones, tablet PCs, smartwatches, watch phones, mobile communication terminals, electronic notebooks, e-book readers, portable multimedia players, navigation systems, Ultra Mobile PCs (UMPCs), televisions, laptops, computer monitors, advertising displays, and Internet of Things (IoT) devices.

The display device 1 may be a light-emitting display device, such as an organic light-emitting display device using organic light-emitting diodes (OLEDs), a quantum dot light-emitting display device including a quantum dot emission layer, an inorganic light-emitting display device including inorganic semiconductors, or a micro-or nano-light-emitting display device using micro-or nano-light-emitting diodes (LEDs). The display device 1 may be described as an organic light-emitting display device, but the present disclosure is not necessarily limited thereto.

The display device 1 includes a display panel 100, a display driving circuit 20, and a circuit board 30. In one aspect, the display panel 100 may include a main area MA and a sub-area SBA.

The display panel 100 may be formed as a rectangular plane with a pair of short sides extending in a first direction DR1 and a pair of long sides extending in a second direction DR2 intersecting the first direction DR1. The display panel 100 may also have a thickness in a third direction DR3 intersecting the first and second directions DR1 and DR2. The corners where the short sides in the first direction DR1 and the long sides in the second direction DR2 meet may be rounded with a predetermined curvature or may be formed at a right angle. The planar shape of the display panel 100 is not necessarily limited to a rectangle and may be formed as a polygon, a circle, or an ellipse. The display panel 100 may be formed flat but is not necessarily limited thereto. For example, the display panel 100 may include curved sections formed at the left and right ends with a constant or varying curvature. Additionally, the display panel 100 may be flexibly formed to be bendable, curvable, foldable, or rollable.

The display panel 100 may include a main area MA and a sub-area SBA. The main area MA may include a display area DA for displaying images and a non-display area NDA surrounding the display area DA. The display area DA may occupy a majority region of the main area MA. The display area DA may be located at the center of the main area MA. The non-display area NDA may be located adjacent to and surrounds the display area DA. The non-display area NDA may be the outer area of the display area DA. The non-display area NDA may be located to surround the display area DA. The non-display area NDA may be the edge area of the display panel 100. A plurality of pixels PX may be located in the display area DA to display an image. As the display area DA includes the pixels PX, the display area DA may be an area for displaying an image. For example, the display area DA may include pixel areas where the pixels PX are located.

The sub-area SBA may extend in the first direction DR1 from one side of the main area MA. The length of the sub-area SBA in the first direction DR1 may be smaller than the length of the main area MA in the first direction DR1. The length of the sub-area SBA in the second direction DR2 may be smaller than or substantially equal to the length of the main area MA in the second direction DR2. The sub-area SBA may be bent and located below the display panel 100. In some cases, for example, at least a region of the sub-area SBA may overlap with a region of the main area MA in the third direction DR3.

In some embodiments, a display driving circuit 20 may be disposed on the sub-area SBA. The display driving circuit 20 may generate signals and voltages for driving the display panel 100. The display driving circuit 20 may be formed as an integrated circuit (IC) and connected to the sub-area SBA of the display panel 100 by a chip-on-glass (COG) method, a chip-on-plastic (COP) method, or an ultrasonic bonding method. In some embodiments, the display driving circuit 20 may be connected to the circuit board 30 by a chip-on-film (COF) method.

The circuit board 30 may be attached to one end of the sub-area SBA of the display panel 100 opposite from the display area DA. In some cases, the circuit board 30 may be electrically connected to the display panel 100 and the display driving circuit 20. The display panel 100 and the display driving circuit 20 may receive digital video data, timing signals, and drive voltages via the circuit board 30. The circuit board 30 may be a flexible printed circuit board (FPCB), a printed circuit board (PCB), or a flexible film such as a COF.

The display device 1 may further include, below the display panel 100, a light-shielding layer to absorb light incident from the outside, a buffer layer to absorb external impacts, and a heat-dissipating layer for efficient heat dissipation of the display panel 100.

The light-shielding layer may block light transmission to prevent the components located below the light-shielding layer from being visible from the top of the display panel 100. The light-shielding layer may include a light-absorbing material such as black pigment or black dye.

The buffer layer may absorb external impacts to prevent damage to the display panel 100. The buffer layer may be formed as a single layer or multiple layers. For example, the buffer layer may be formed of a polymer resin such as polyurethane, polycarbonate, polypropylene, or polyethylene, or may include an elastic material such as foam-molded sponge formed from rubber, a urethane-based material, or an acrylic-based material.

The heat-dissipating layer may include a first heat-dissipating layer including a material such as graphite or carbon nanotubes, and a second heat-dissipating layer formed as a thin metal film with excellent thermal conductivity and electromagnetic wave shielding properties, formed of a metal such as copper, nickel, iron, or silver.

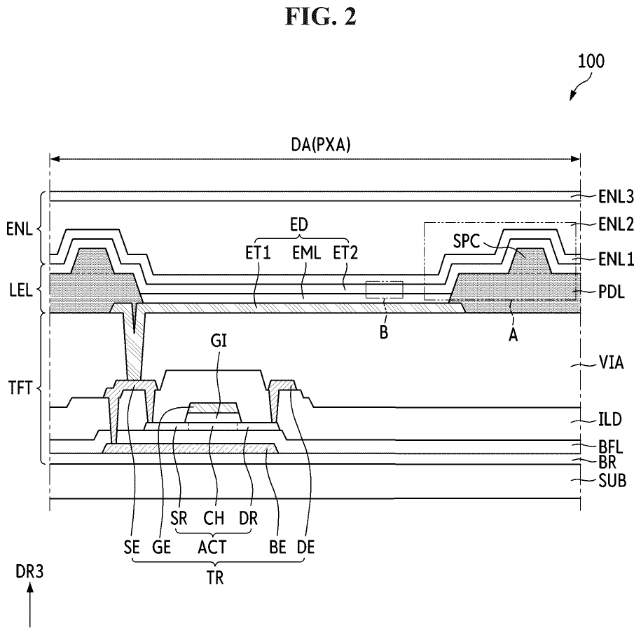

FIG. 2 is a cross-sectional view of a display panel according to an embodiment of the present disclosure. For example, FIG. 2 illustrates a portion of the display area DA of the display panel 100. In FIG. 2, as an example, the display panel 100 may be a light-emitting display panel including light-emitting elements ED (e.g., organic light-emitting diodes (OLEDs).

Referring to FIG. 2, the display panel 100 may include a substrate SUB (or a base layer), a thin-film transistor layer TFT, a light-emitting element layer LEL, and an encapsulation layer ENL. The thin-film transistor layer TFT, the light-emitting element layer LEL, and the encapsulation layer ENL may be sequentially stacked on the substrate SUB. For example, relative to the display area DA, the thin-film transistor layer TFT, the light-emitting element layer LEL, and the encapsulation layer ENL may be sequentially arranged along the third direction DR3 on the substrate SUB.

In one embodiment, the display panel 100 may further include additional elements disposed above and/or below the encapsulation layer ENL. For example, the display panel 100 may further include at least one of a sensor layer (e.g., a touch sensor layer), an optical layer (e.g., a color filter layer and/or a wavelength conversion layer), or a protective layer (e.g., a protective film, an insulating layer, an upper substrate, and/or a window). Each of the sensor layer, the optical layer, and/or the protective layer may be disposed above the encapsulation layer ENL or between the light-emitting element layer LEL and the encapsulation layer ENL.

The substrate SUB, which is a base member for forming the display panel 100, may be rigid or flexible. In one embodiment, the substrate SUB may include an insulating material such as glass. The substrate SUB may be a substrate with rigid properties, and might not be bendable. In an embodiment, the substrate SUB may include polyimide or an insulating material, and may be a flexible substrate capable of deformation such as bending, folding, or rolling. The substrate SUB may or might not be bent.

The thin-film transistor layer TFT (e.g., a backplane circuit layer or a thin-film transistor layer) may be disposed on the substrate SUB. The thin-film transistor layer TFT may include wirings (e.g., signal lines and power lines) and circuit elements of pixels PX. For example, the circuit elements include pixel transistors PXT and capacitors C.

In one embodiment, transistors TR may be formed simultaneously using the same material and may have substantially identical or similar cross-sectional structures. For example, the transistors TR of the pixels PX may be formed simultaneously using the same oxide semiconductor and may have substantially identical or similar cross-sectional structures. For example, active layers ACT of the transistors TR may be disposed in the same layer (e.g., above a buffer layer BFL) within the thin-film transistor layer TFT and may include the same oxide semiconductor.

The thin-film transistor layer TFT may include a plurality of conductive layers. In some cases, at least one semiconductor layer is disposed on the substrate SUB (or on a barrier layer BR). Additionally, the thin-film transistor layer TFT may further include a plurality of insulating layers and/or insulating patterns disposed on the substrate SUB (or on the barrier layer BR).

Patterns included in the conductive layers of the thin-film transistor layer TFT may include electrodes that form the circuit elements of the thin-film transistor layer TFT, and conductive patterns and/or wirings connected to the circuit elements. The patterns in the conductive layers of the thin-film transistor layer TFT (e.g., electrodes, conductive patterns, and/or wirings in each conductive layer) may include at least one conductive material. For example, the patterns in the conductive layers of the thin-film transistor layer TFT may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), or other metals, alloys thereof, or other conductive materials. In one embodiment, patterns included in the same conductive layer may be formed simultaneously using the same conductive material.

Patterns included in the semiconductor layer of the thin-film transistor layer TFT may include active layers ACT of transistors disposed in the thin-film transistor layer TFT. In one embodiment, active layers ACT of the pixel transistors PXT and active layers ACT of circuit transistors may be formed simultaneously using the same semiconductor material (e.g., the same oxide semiconductor). Accordingly, active layers ACT of the transistors TR and the active layers ACT of the circuit transistors may be disposed in the same layer and may include the same semiconductor material.

The insulating layers and/or insulating patterns of the thin-film transistor layer TFT may include a barrier layer BR, a buffer layer BFL, a gate insulating layer GI, an interlayer insulating layer ILD, and a planarization layer VIA sequentially stacked and disposed on the substrate SUB along the third direction DR3. The insulating layers and/or insulating patterns of the thin-film transistor layer TFT may each include an inorganic or organic insulating material and may be formed as a single layer or a multilayer.

In one embodiment, at least one of the insulating layers of the thin-film transistor layer TFT may be disposed across the entire display area DA. For example, the barrier layer BR, the buffer layer BFL, the interlayer insulating layer ILD, and the planarization layer VIA may be located in the entire display area DA.

The structure of the thin-film transistor layer TFT is described layer by layer. The barrier layer BR may be disposed on the substrate SUB. The barrier layer BR may include at least one inorganic insulating layer including an inorganic insulating material (e.g., silicon nitride (SiNₓ), silicon oxide (SiOₓ), silicon oxynitride (SiON), titanium oxide (TiOₓ), aluminum oxide (AlₓO_{y}), or other inorganic insulating materials). The barrier layer BR may protect the pixels PX by preventing moisture penetration through the substrate SUB. In an embodiment, the thin-film transistor layer TFT might not include the barrier layer BR.

A first conductive layer (e.g., a lower conductive layer) may be disposed on the barrier layer BR (or the substrate SUB). For example, the first conductive layer may include a bottom electrode BE (or a light-blocking layer) of at least one transistor TR. For example, the bottom electrode BE (or the light-blocking layer) of the transistor TR may be disposed on the barrier layer BR. The bottom electrode BE may be disposed below the active layer ACT of the transistor TR to overlap with a channel region CH of the transistor TR. In one embodiment, the bottom electrode BE may also overlap at least part of a source region SR and a drain region DR of the transistor TR, but the present disclosure is not necessarily limited thereto. The patterns of the first conductive layer, including the bottom electrode BE, may each include at least one conductive material and may be formed as a single layer or multilayer.

In one embodiment, the bottom electrode BE may be electrically connected to one electrode of the transistor TR (e.g., a source electrode SE) and may be utilized as an electrode for adjusting the characteristics of the transistor TR. For example, the bottom electrode BE may be electrically connected to the source electrode SE of the transistor TR. When the bottom electrode BE is electrically connected to one electrode of the transistor TR, the bottom electrode BE may also be considered a component of the transistor TR. By placing the bottom electrode BE below the active layer ACT of the transistor TR, external light incident on the channel region CH and other parts of the transistor TR can be blocked. In one embodiment, when the thin-film transistor layer TFT does not include the bottom electrode BE or the light-blocking layer, the first conductive layer may be excluded. In some cases, the bottom electrode BE may cover a portion of an upper layer of the barrier layer BR.

The buffer layer BFL may be disposed on the barrier layer BR and the bottom electrode BE. The buffer layer BFL may include at least one inorganic insulating layer including an inorganic insulating material (e.g., SiNₓ, SiOₓ, SiON, TiOₓ, AlₓO_{y}, or other inorganic insulating materials).

The buffer layer BFL may include an insulating material that serves as a barrier to prevent diffusion of oxygen, hydrogen, or other elements. In addition to a silicon nitride film including SiNₓ and a silicon oxide film including SiOₓ, the buffer layer BFL may include other insulating materials capable of preventing the penetration or diffusion of oxygen, hydrogen, and/or moisture.

The active layer ACT may include the channel, source, and drain regions CH, SR, and DR. The channel region CH, in a plan view, may overlap with a gate electrode GE in the third direction DR3 and may be disposed between the source and drain regions SR and DR along a horizontal direction (e.g., the first direction DR1 or the second direction DR2). The source and drain regions SR and DR may each be disposed on an end of the channel region CH, and may be spaced apart from each other across the channel region CH. The source and drain regions SR and DR (or portions thereof) might not overlap with the gate electrode GE in the plan view. The carrier concentration (e.g., electron concentration) of the source and drain regions SR and DR may be higher than that of the channel region CH.

In one embodiment, the active layer ACT may include an oxide semiconductor. For example, the active layer ACT may include an oxide semiconductor including at least one of indium (In), gallium (Ga), zinc (Zn), tin (Sn), or hafnium (Hf), or other oxide semiconductors. For example, the active layer ACT may include at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO), or indium-tin-gallium-zinc oxide (ITGZO), or other oxide semiconductors.

In some embodiments, the active layers ACT of some transistors disposed within the thin-film transistor layer TFT may be disposed on the buffer layer BFL. In one embodiment, at least one transistor TR may be disposed in each pixel area PXA. Accordingly, a plurality of transistors TR may be disposed in the display area DA.

The gate insulating layer GI may be disposed on an active layer ACT. For example, the gate insulating layer GI may be disposed on a portion of an active layer ACT that includes a channel region CH. In some cases, the gate insulating layer GI may be disposed on and cover the channel region CH. In some cases, the gate insulating layer GI may cover a portion of the source region SR and a portion of the drain region DR.

The gate insulating layer GI may include at least one inorganic insulating layer including an inorganic insulating material (e.g., SiNₓ, SiOₓ, SiON, TiOₓ, AlₓO_{y}, or other inorganic insulating materials).

In one embodiment, the gate insulating layer GI may be etched to cover a portion of the active layer ACT included in the transistor TR while exposing other portions of the active layer ACT. For example, in the region where the transistor TR is located, the gate insulating layer GI may cover the channel region CH of the active layer ACT included in the transistor TR while exposing the source and drain regions SR and DR of the active layer ACT.

As the gate insulating layer GI exposes the source and drain regions SR and DR, the conductivity of the source and drain regions SR and DR can be appropriately and/or efficiently enhanced during the manufacture of the display panel 100. For example, when etching the gate insulating layer GI to expose at least portions of the source and drain regions SR and DR, oxygen vacancies are generated in the source and drain regions SR and DR. These vacancies may increase the carrier concentration in the source and drain regions SR and DR in subsequent processes (e.g., the process of forming the interlayer insulating layer ILD), a thus a separate doping process may be avoided.

However, the present disclosure is not necessarily limited thereto. In an embodiment, for example, the gate insulating layer GI may entirely cover the active layer ACT, except for a contact hole for connecting the transistor TR to another circuit element or a wiring, in some or all of the transistors included in the thin-film transistor layer TFT. In some cases, a drain electrode DE of the transistor TR or a source electrode SE of the transistor TR may be disposed on the active layer ACT through the contact hole.

A second conductive layer (e.g., a gate conductive layer) including the gate electrode GE may be disposed on the gate insulating layer GI. For example, the gate electrode GE of the transistor TR may be disposed on the gate insulating layer GI covering the channel region CH of the transistor TR. The patterns in the second conductive layer, including the gate electrodes GE, may each include at least one conductive material and may be formed as a single layer or a multilayer.

The interlayer insulating layer ILD may be disposed on the buffer layer BFL, the semiconductor layer including the active layer ACT, the gate insulating layer GI, and the second conductive layer including the gate electrode GE. For example, the interlayer insulating layer ILD may be disposed on the buffer layer BFL to cover the semiconductor layer, the gate insulating layer GI, and the patterns of the second conductive layer. The interlayer insulating layer ILD may include at least one inorganic insulating layer including an inorganic insulating material. In some cases, the upper surface of the interlayer insulating layer ILD might not be substantially flat. However, embodiments are not necessarily limited thereto.

A third conductive layer (e.g., a source-drain conductive layer) including the source electrode SE of the transistor TR, a drain electrode DE of the transistor TR, and/or conductive patterns electrically connected to the transistor TR may be disposed on the interlayer insulating layer ILD. For example, the third conductive layer may include the source and drain electrodes SE and DE of the transistor TR. The patterns in the third conductive layer may each include at least one conductive material and may be formed as a single layer or a multilayer.

The source and drain electrodes SE and DE of the transistor TR may be electrically connected to the source and drain regions SR and DR, respectively, of the transistor TR, penetrating the interlayer insulating layer ILD. In one embodiment, the source electrode SE of the transistor TR may be electrically connected to the bottom electrode BE of the transistor TR, penetrating the interlayer insulating layer ILD and the buffer layer BFL.

The planarization layer VIA may be disposed on and cover the transistor TR. For example, the planarization layer VIA may be disposed on the interlayer insulating layer ILD and the third conductive layer. The planarization layer VIA may include at least one organic insulating layer including an organic insulating material (e.g., acrylic resin, epoxy resin, phenolic resin, polyamide resin, polyimide resin, or other organic insulating materials). The planarization layer VIA may or might not include an inorganic insulating layer. The surface of the planarization layer VIA (e.g., the upper surface) may be substantially flat. In some cases, the planarization layer VIA may be the uppermost layer of the thin-film transistor layer TFT.

The light-emitting element layer LEL may be disposed on the thin-film transistor layer TFT. For example, the light-emitting element layer LEL may be disposed on the planarization layer VIA and may be located at least in the display area DA.

The light-emitting element layer LEL may include a light-emitting element ED for each of the pixels PX. For example, the light-emitting element layer LEL may include a pixel-defining layer PDL (also referred to as a “bank”) that represent an emission region of each of the pixels PX, and a light-emitting element ED disposed in the emission region. In one embodiment, the light-emitting element layer LEL may further include a spacer SPC disposed on portions of the pixel-defining layer PDL.

The light-emitting element ED may include a first electrode ET1 disposed in the emission region, a light-emitting layer EML disposed on the first electrode ET1, and a second electrode ET2 disposed on the light-emitting layer EML. The first electrode ET1 of the light-emitting element ED may be electrically connected to the transistor TR in the corresponding pixel PX, penetrating the planarization layer VIA. In some cases, the first electrode ET1 of the light-emitting element ED may be electrically connected to source electrode SE of the transistor TR.

The first electrode ET1 of the light-emitting element ED may be a single-layer or a multilayer electrode including at least one conductive material. In one embodiment, the display panel 100 may be a front-emission display panel, and the first electrode ET1 may include a reflective electrode layer including at least one of Al, Mo, Ti, Cu, Ag, Mg, Pt, Pd, Au, Ni, Nd, Ir, Cr, or other reflective conductive materials.

The light-emitting layer EML of the light-emitting element ED may include a polymer material or a small-molecule material. Light emitted from the light-emitting layer EML may be used for displaying an image.

FIG. 2 illustrates a display panel 100 in which the light-emitting layer EML of the light-emitting element ED is individually formed in each pixel area PXA, but the present disclosure is not necessarily limited thereto. For example, the display panel 100 may include tandem-structure light-emitting elements having a common light-emitting layer EML formed over the entire display area DA.

The second electrode ET2 of the light-emitting element ED may include a conductive material. In one embodiment, the second electrode ET2 may be formed as a common layer covering the light-emitting layer EML and the pixel-defining layer PDL over the entire display area DA. In one embodiment, the display panel 100 may be a front-emission display panel, and the second electrode ET2 may include a transparent or semi-transparent electrode layer. In an embodiment, the second electrode ET2 may be disposed on and cover the light-emitting layer EML, the pixel-defining layer PDL, and the spacers SPC over the entire display area DA.

The second electrode ET2 may be formed of a transparent conductive oxide (TCO) such as indium tin oxide (ITO) or IZO, or a semi-transparent conductive material such as Mg, Ag, or an alloy of Mg and Ag. In some cases, when the second electrode ET2 is formed of a semi-transparent conductive material, the light extraction efficiency of the light-emitting element ED can be enhanced by a microcavity effect.

The pixel-defining layer PDL may have an opening corresponding to the emission region and may surround the emission region. For example, the pixel-defining layer PDL may be formed to cover the edge portions of the first electrode ET1 of the light-emitting element ED and may include an opening exposing an upper surface of the first electrode ET1. The region where the exposed first electrode ET1 and the light-emitting layer EML overlap may be the emission region of the corresponding pixel PX. In one embodiment, the pixel-defining layer PDL may be formed of an organic material. The pixel-defining layer PDL may include a light-blocking material. The pixel-defining layer PDL may include a base resin and a colorant. The base resin may include at least one of a cardo resin, an epoxy resin, an acrylate resin, a siloxane resin, or a polyimide resin. The colorant may be a carbon-based pigment, a metal oxide pigment, or an organic pigment. For example, the carbon-based pigment may include carbon black, carbon nanotubes, titanium black, or vertically aligned nanotube array (VANTA) black, but is not necessarily limited thereto. For example, the metal oxide pigment may include titanium black (TiNₓO_{y}) or a Cu—Mn—Fe-based black pigment, but is not necessarily limited thereto. For example, the organic pigment may include lactam black, perylene black, or aniline black, but is not necessarily limited thereto. In some cases, the colorant may be a mixture of two or more pigments or dyes of different colors, but is not necessarily limited thereto.

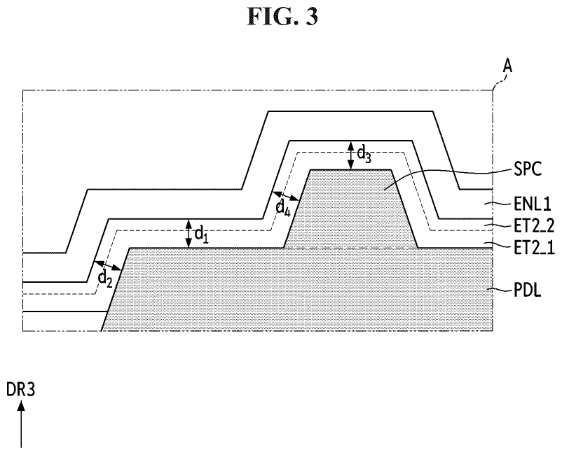

The spacer SPC may be disposed on a portion of an upper surface of the pixel-defining layer PDL. The spacer SPC may include at least one organic insulating layer including an organic insulating material. The spacer SPC may include the same material as, or a different material from, the pixel-defining layer PDL. The pixel-defining layer PDL and the spacer SPC may be sequentially formed through respective mask processes or formed simultaneously and/or integrally using a halftone mask. In some cases, the second electrode ET2 may be disposed to cover the pixel-defining layer PDL, the spacer SPC, and the light-emitting layer EML. Further detail on the second electrode ET2 is described with reference to FIGS. 3-5 and 11-14.

The encapsulation layer ENL may be disposed on the light-emitting element layer LEL. The encapsulation layer ENL may cover the light-emitting element layer LEL in the display area DA and extend to the non-display area NDA to contact the thin-film transistor layer TFT. In some cases, the encapsulation layer ENL may cover side surfaces of the light-emitting element layer LEL in the non-display area NDA. The encapsulation layer ENL may block oxygen or moisture from penetrating the light-emitting element layer LEL, and may mitigate electrical and/or physical impacts on the thin-film transistor layer TFT and the light-emitting element layer LEL.

In one embodiment, the encapsulation layer ENL may include a first encapsulation layer ENL1, a second encapsulation layer ENL2, and a third encapsulation layer ENL3 sequentially disposed on the light-emitting element layer LEL. The first and third encapsulation layers ENL1 and ENL3 may be inorganic encapsulation layers including an inorganic material. The second encapsulation layer ENL2 may be an organic encapsulation layer including an organic material. In some cases, the first encapsulation layer ENL1 may have a uniform thickness and covers the second electrode ET2. In some cases, an upper surface of the second encapsulation layer ENL2 may be substantially flat. In some cases, the third encapsulation layer ENL3 may have a uniform thickness and cover the second encapsulation layer ENL2.

FIG. 3 is an enlarged cross-sectional view of area A of FIG. 2. Referring to FIG. 3, the second electrode ET2 may include a first sub-electrode ET2_1 and a second sub-electrode ET2_2. The thickness of the second electrode ET2 may range from 10 Å to 1,000 Å.

The first and second sub-electrodes ET2_1 and ET2_2 may be too thin to be identified using an electron microscope such as a scanning electron microscope (SEM) or transmission electron microscope (TEM). The thicknesses of the first and second sub-electrodes ET2_1 and ET2_2 may be measured using an X-ray photoelectron spectroscopy (XPS) depth profile. The second electrode ET2 may be formed using an atomic layer deposition (ALD) method, and thus the second electrode ET2 may be formed with a thin and uniform thickness.

For example, when the second electrode ET2 is formed on the pixel-defining layer PDL and the spacer SPC, a thickness of the second electrode ET2 may include a first thickness d₁, a second thickness d₂, a third thickness d₃, and a fourth thickness d₄. For example, the first thickness d₁ of the second electrode ET2 (e.g., measured from the upper surface of the pixel-defining layer PDL) may be within the range of 90% to 100% of a second thickness d₂ of the second electrode ET2 (e.g., measured from the side surfaces of the pixel-defining layer PDL). For example, when the second thickness d₂ is 100 Å, the first thickness d₁ may range from 90 Å to 100 Å.

A third thickness d₃ of the second electrode ET2 (e.g., measured from the upper surface of the spacer SPC) may be within the range of 90% to 100% of a fourth thickness d₄ of the second electrode ET2 (e.g., measured from the side surfaces of the spacer SPC). For example, when the fourth thickness d₄ is 100 Å, the third thickness d₃ may range from 90 Å to 100 Å.

Since the second electrode ET2 is formed with uniform thicknesses on the upper surfaces and side surfaces of the pixel-defining layer PDL and the spacer SPC, cracks and other defects in the second electrode ET2 can be prevented or reduced. Accordingly, the durability of the display device 1 can be enhanced.

In some cases, the second electrode ET2 is formed by sputtering Ag/Mg to a thickness of approximately 10 nm, and thus the second electrode ET2 may have a low resistance. However, uneven deposition surfaces may lead to disconnections (open circuits). To prevent this, after forming an Ag/Mg layer as the second electrode ET2, an auxiliary electrode may be additionally formed on the Ag/Mg layer. The auxiliary electrode may include at least one of ITO, ZnO, ZTO, IZO, IGO, IGZO, IGTO, indium-tin-zinc oxide (ITZO), aluminum-doped zinc oxide (AZO), gallium-doped zinc oxide (GZO), or gallium-tin oxide (GTO).

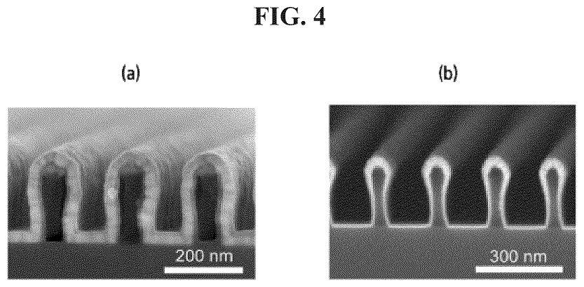

FIG. 4 shows an example of cross-sectional images of wire grid polarizers with indium oxide deposited thereon using SEM. FIG. 4 shows an image (a) depicting a cross-sectional SEM image of a wire grid polarizer with indium oxide deposited thereon by ALD, and image (b) depicting a cross-sectional SEM image of a wire grid polarizer with indium oxide deposited thereon by sputtering.

Referring to image (a), the example illustrates that indium oxide is uniformly deposited on the side surfaces and upper surface of the wire grid polarizer when using ALD. On the other hand, referring to image (b), the example illustrates that indium oxide is deposited more thickly on the upper surface of the wire grid polarizer than on the side surfaces of the wire grid polarizer when using sputtering. For example, the ALD method generates more uniform deposition on the upper surface and side surfaces of the wire grid polarizer compared to the sputtering method.

The second electrode ET2 may include at least one of indium oxide, zinc oxide, tin oxide, or gallium oxide. In some cases, the second electrode ET2 may include indium oxide and zinc oxide. For example, when the first sub-electrode ET2_1 includes indium oxide and the second sub-electrode ET2_2 includes zinc oxide, the thickness of the first sub-electrode ET2_1 may be at least 10 times greater than the thickness of the second sub-electrode ET2_2. The greater the thickness of the first sub-electrode ET2_1 compared to the thickness of the second sub-electrode ET2_2, the higher the electrical conductivity that can be achieved. In one aspect, the first sub-electrode ET2_1 includes indium oxide with higher electrical conductivity and the second sub-electrode ET2_2 includes zinc oxide with lower electrical conductivity.

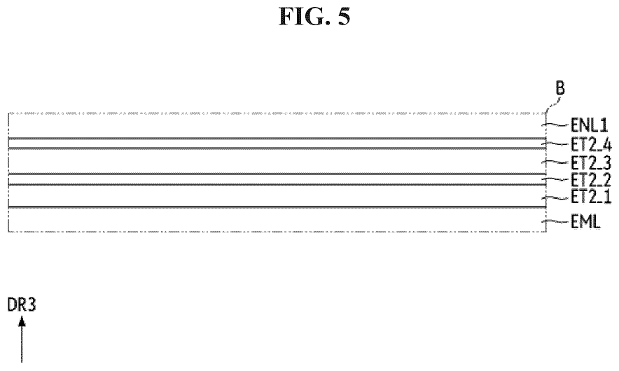

FIG. 5 is an enlarged cross-sectional view of area B of FIG. 2. Referring to FIG. 5, the second electrode ET2 may further include a third sub-electrode ET2_3 and a fourth sub-electrode ET2_4.

Multiple layers of first, second, third, and fourth sub-electrodes ET2_1, ET2_2, ET2_3, and ET2_4 may be arranged in the second electrode ET2 to achieve a target thickness. The first, second, third, and fourth sub-electrodes ET2_1, ET2_2, ET2_3, and ET2_4 may each exhibit crystallinity when having a thickness of 20 Å or greater.

In some cases, the crystallinity may correspond to at least one of the (222), (100), or (002) crystal orientations. The (100) crystal orientation refers to a crystallographic plane that intersects one axis while remaining parallel to the other two in cubic crystal structures. The (002) crystal orientation appears in tetragonal or hexagonal crystals and indicates a preferred alignment along the c-axis, often associated with high-quality vertical crystal growth that enhances electronic, optical, or piezoelectric properties. The (222) crystal orientation is a higher-order reflection within face-centered cubic (FCC) structures, related to the (111) family of planes.

In some cases, when having a thickness less than 20 Å, the first, second, third, and fourth sub-electrodes ET2_1, ET2_2, ET2_3, and ET2_4 may be in an amorphous state. In some cases, the amorphous state refers to a solid material where the atoms or molecules are not arranged in a long-range, orderly crystal structure. Instead, the atoms or molecules are arranged in a random, disordered manner, similar to the atomic arrangement in liquids, but the material is rigid like a solid.

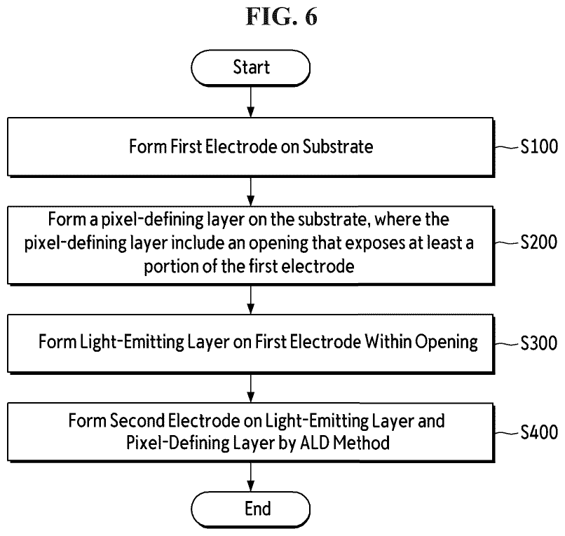

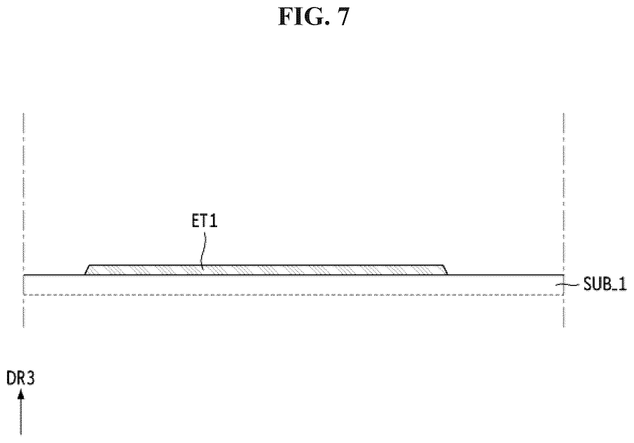

FIG. 6 is a flowchart illustrating a method for manufacturing a display device according to an embodiment of the present disclosure. FIG. 7 is a cross-sectional view illustrating a substrate and a first electrode in step S100 of FIG. 6.

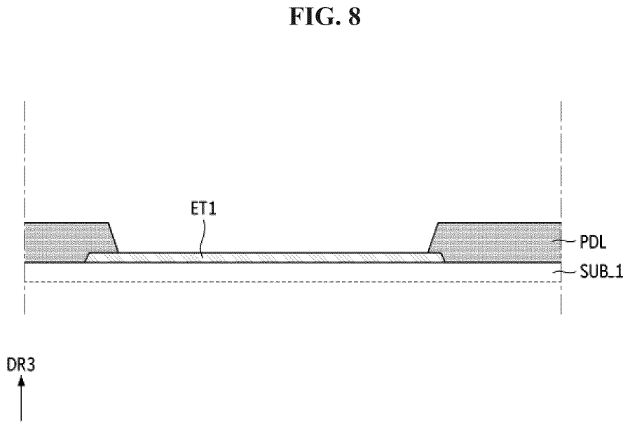

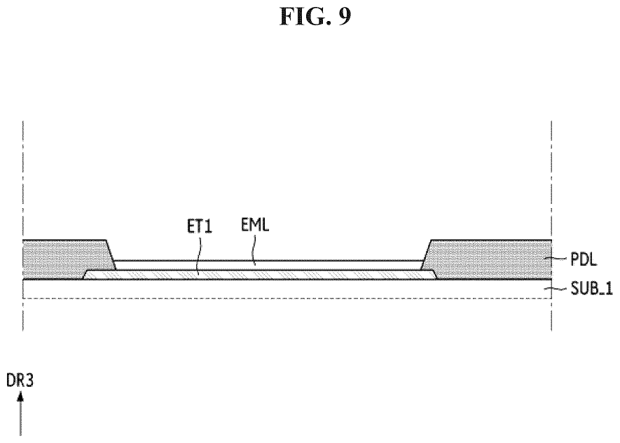

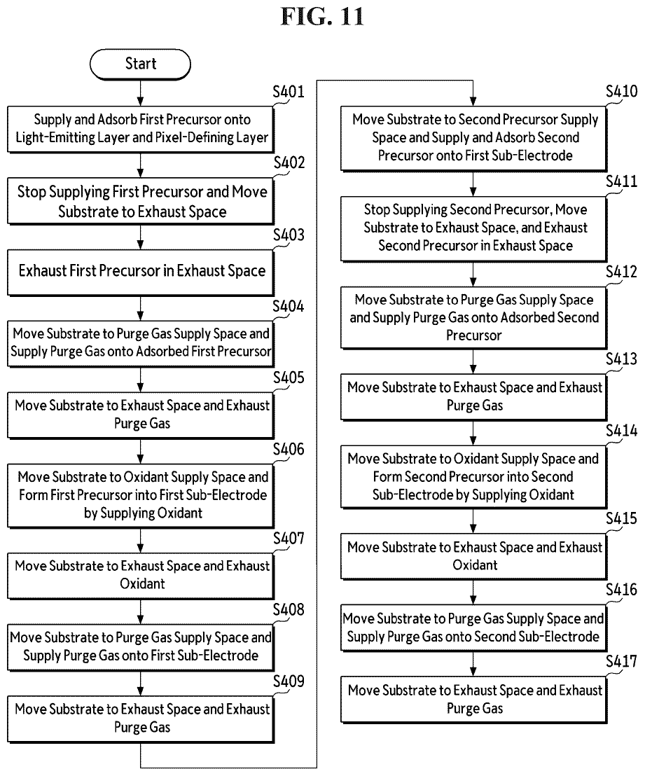

Referring to FIG. 6, at step S110, the method for manufacturing the display device includes forming a first electrode on a substrate. Further detail on forming the first electrode is described with reference to FIG. 7. At step S200, the method for manufacturing the display device includes forming a pixel-defining layer on the substrate, where the pixel-defining layer include an opening that exposes at least a portion of the first electrode. Further detail on forming the pixel-defining layer is described with reference to FIG. 8. At step S300, the method for manufacturing the display device includes forming a light-emitting layer on the first electrode within the opening of the pixel-defining layer. Further detail on forming the light-emitting layer is described with reference to FIG. 9. At step S400, the method for manufacturing the display device includes forming a second electrode on the light-emitting layer and the pixel-defining layer using an ALD method. Further detail on forming the second electrode is described with reference to FIG. 11.

Referring to FIG. 7, a first electrode ET1 may be formed on a substrate SUB_1. In one embodiment, the substrate SUB_1 may include a display area DA with a plurality of pixel areas PXA, and a thin-film transistor layer TFT may be formed on the substrate SUB_1. Thereafter, the first electrode ET1 may be formed in each pixel area PXA on the substrate SUB_1 where the thin-film transistor layer TFT is formed. The first electrode ET1 may be formed using the aforementioned materials, and the method to form the first electrode ET1 is not necessarily limited.

FIG. 8 is a cross-sectional view illustrating the substrate, the first electrode, and a pixel-defining layer in step S200 of FIG. 6. At step S200, the method for manufacturing the display device includes forming a pixel-defining layer on the substrate, the pixel-defining layer including an opening that exposes at least a portion of the first electrode.

Referring to FIG. 8, a pixel-defining layer PDL may be formed on the substrate SUB_1 and a portion of the first electrode ET1. In one aspect, the pixel-defining layer includes at least one opening that exposes a portion of the first electrode. This opening represents the emission area EA where the light-emitting layer will later be deposited. The pixel-defining layer PDL may be formed using the aforementioned materials, and the method to form the pixel-defining layer PDL is not necessarily limited.

FIG. 9 is a cross-sectional view illustrating the substrate, the first electrode, the pixel-defining layer, and a light-emitting layer in step S300 of FIG. 6. At step S300, the method for manufacturing the display device includes forming a light-emitting layer on the first electrode within the opening of the pixel-defining layer.

Referring to FIG. 9, a light-emitting layer EML may be formed on the first electrode ET1 in each emission area EA of the pixel-defining layer PDL. In some cases, the light-emitting layer EML is disposed on the exposed portion of the first electrode within the opening (e.g., emission area EA) of the pixel-defining layer. The light-emitting layer EML may be formed using the aforementioned materials, and the method to form the light-emitting layer EML is not necessarily limited.

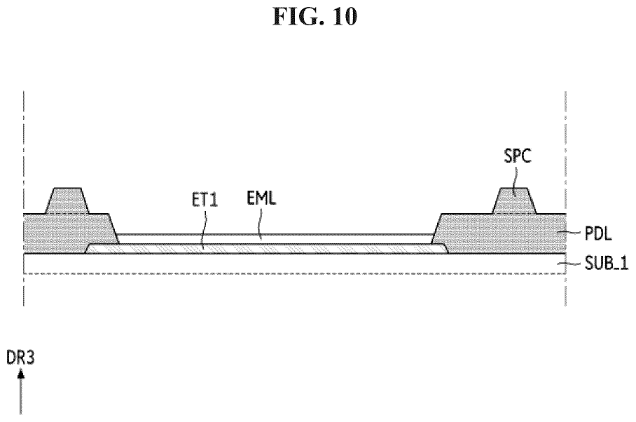

FIG. 10 is a cross-sectional view of a substrate, a first electrode, a pixel-defining layer, a light-emitting layer, and a spacer according to an embodiment of the present disclosure. Referring to FIG. 10, the method for manufacturing a display device according to the embodiment of FIG. 6 may further include forming a spacer SPC on the pixel-defining layer PDL. The spacer SPC may be formed using the aforementioned materials, and the method to form the spacer SPC is not necessarily limited.

FIG. 11 is a flowchart illustrating a method for manufacturing a second electrode according to an embodiment of the present disclosure. The method for manufacturing the second electrode includes sequentially supplying precursors, purge gas, and oxidant using an ALD method to form the second electrode on the light-emitting layer and the pixel-defining layer.

Referring to FIG. 11, at step S401, the method includes supplying and adsorbing a first precursor onto the light-emitting layer and pixel-defining layer. At step S402, the method includes stopping supplying the first precursor and moving the substrate to an exhaust space. At step S403, the method includes exhausting an excess of the first precursor in the exhaust space. At step S404, the method includes moving the substrate to a purge gas supply space and supplying purge gas onto the adsorbed first precursor. At step S405, the method includes moving the substrate to the exhaust space and exhausting the purge gas.

At step S406, the method includes moving the substrate to an oxidant supply space and forming a first sub-electrode by supplying oxidant to convert the first precursor. At step S407, the method includes moving the substrate to the exhaust space and exhausting the oxidant. At step S408, the method includes moving the substrate to the purge gas supply space and supplying purge gas onto the first sub-electrode. At step S409, the method includes moving the substrate to the exhaust space and exhausting the purge gas. At step S410, the method includes moving the substrate to a second precursor supply space and supplying and adsorbing a second precursor onto the first sub-electrode.

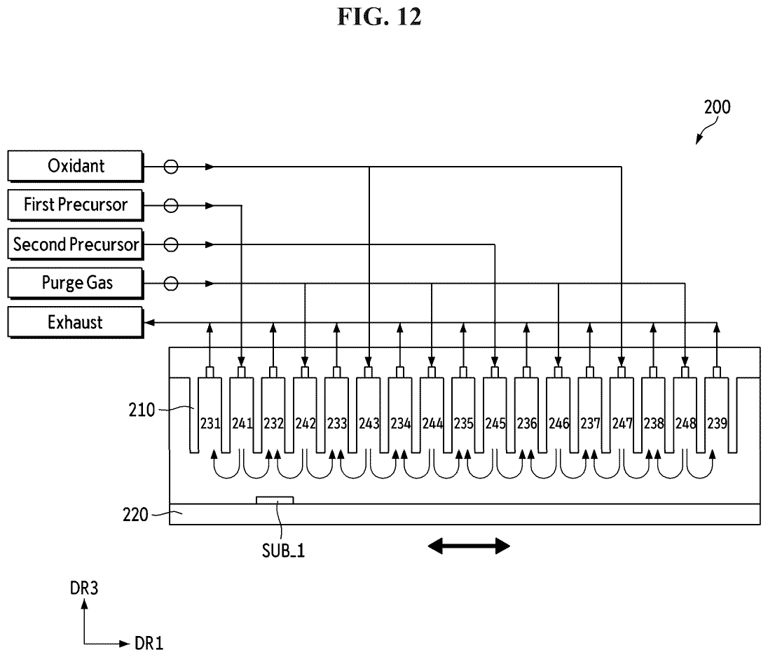

At step S411, the method includes stopping supplying the second precursor, moving the substrate to the exhaust space, and exhausting an excess of the second precursor in the exhaust space. At step S412, the method includes moving the substrate to the purge gas supply space and supplying purge gas onto the adsorbed second precursor. At step S413, the method includes moving the substrate to the exhaust space and exhausting the purge gas. At step S414, the method includes moving the substrate to the oxidant supply space and forming a second sub-electrode by supplying oxidant to convert the second precursor. At step S415, the method includes moving the substrate to the exhaust space and exhausting the oxidant. At step S416, the method includes moving the substrate to the purge gas supply space and supplying purge gas onto the second sub-electrode. At step S417, the method includes moving the substrate to the exhaust space and exhausting the purge gas. Further detail on the method for manufacturing the second electrode is described with reference to FIG. 12.

A second electrode ET2 may include a first sub-electrode ET2_1 and a second sub-electrode ET2_2, and the first and second sub-electrodes ET2_1 and ET2_2 may include different materials. The second electrode ET2 may be formed using a spatial ALD method within a single chamber (e.g., a deposition chamber).

In conventional ALD methods, deposition is performed using a single precursor within one chamber. To deposit different materials on the same substrate, for example, a first material may be deposited in a first chamber, and then a second material may be deposited in a second chamber. During the transfer of the substrate from the first chamber to the second chamber, the substrate may be exposed to the external environment, resulting in the formation of particles on the surface of the substrate. Additionally, creating a vacuum environment for each chamber may increase process time and cost.

In contrast, with spatial ALD, two or more materials can be deposited within one chamber. Accordingly, manufacturing the second electrode using the spatial ALD process can reduce process time and minimize the formation of particles on the surface of a substrate.

FIG. 12 is a cross-sectional view of a spatial ALD chamber according to an embodiment of the present disclosure. Referring to FIG. 12, a spatial ALD chamber 200 may include partitions 210, a transport unit 220, first through ninth exhaust units 231 through 239, and first through eighth supply units 241 through 248. The arrows illustrated in FIG. 12 may indicate the flow directions of gases. In an embodiment, each of the first through ninth exhaust units 231 through 239 and each of first through eighth supply units 241 through 248 may be arranged alternately along a direction parallel to the surface of the substrate SUB_1. The interior of the spatial ALD chamber 200 may be under a vacuum or low-pressure condition.

A plurality of partitions 210 may be formed as physical partitions or gas streams. The partitions 210 may spatially separate the first through ninth exhaust units 231 through 239, and the first through eighth supply units 241 through 248. The lower parts of the partitions 210 may extend towards the surface of the transport unit 220. A substrate SUB_1 to be subject to deposition may be provided on the transport unit 220. The substrate SUB_1 on the transport unit 220 may move horizontally (e.g., left to right, or vice versa). The lower parts of the partitions 210 may be spaced apart from the surface of the substrate SUB_1 by a predetermined distance to allow gases injected onto the surface of the substrate SUB_1 to flow around the lower parts of the partitions 210 and toward the first through ninth exhaust units 231 through 239 after reacting with the surface of the substrate SUB_1. The partitions 210, which are physical barriers for the gases injected onto the substrate SUB_1, may limit cross-contamination between precursors. The arrangement illustrated in FIG. 12, however, is merely example and should not be construed as limiting the scope of the present disclosure.

An oxidant, a first precursor, and a second precursor may be plasma-treated before being injected into the spatial ALD chamber 200. The first and second precursors may include at least one of indium, zinc, tin, aluminum, or gallium. The first and second precursors may include at least one of 3-(dimethylaminopropyl) dimethylindium (DADI), diethyl zinc (DEZ), triethylgallium (TEG), or diethyl tin (DET). The process of forming the second electrode ET2 is described with reference to FIGS. 11 and 12.

The substrate SUB_1, where a first electrode ET1, a pixel-defining layer PDL, and a light-emitting layer EML are formed, is transported via the transport unit 220 below the first supply unit 241. The first precursor is supplied from the first supply unit 241 and adsorbed onto the light-emitting layer EML and the pixel-defining layer PDL (e.g., step S401).

Then, the supply of the first precursor is stopped, and the substrate SUB_1 is transported via the transport unit 220 below the second exhaust unit 232 (e.g., step S402). The second exhaust unit 232 then exhausts or removes the unadsorbed first precursor or residual byproducts remaining on the substrate SUB_1 after deposition of the first precursor (e.g., step S403).

Then, the substrate SUB_1 is transported via the transport unit 220 below the second supply unit 242, and a purge gas is supplied to the substrate SUB_1 on which the first precursor has been adsorbed (e.g., step S404). The purge gas may include an inert gas such as nitrogen (N₂), argon (Ar), or helium (He). By injecting the purge gas onto the substrate SUB_1, the unreacted first precursor remaining in the spatial ALD chamber 200 before exposing the substrate SUB_1 to the second precursor may be removed. The second, fourth, sixth, and eighth supply units 242, 244, 246, and 248 that supply the purge gas may be positioned between the first and fifth supply units 241 and 245 that supply the first and second precursors, respectively, to prevent cross-contamination between the first and second precursors.

Then, the substrate SUB_1 is transported via the transport unit 220 below the third exhaust unit 233, and the purge gas is exhausted or removed through the third exhaust unit 233 (e.g., step S405). The first through ninth exhaust units 231 through 239 may be alternatively arranged with the first through eighth supply units 241 through 248. Gases and/or byproducts supplied from the first through eighth supply units 241 through 248 may be exhausted through the first through ninth exhaust units 231 through 239. The placement of the first through ninth exhaust units 231 through 239 minimizes contamination on the substrate SUB_1 by exhausting gases and/or byproducts supplied by the first through eighth supply units 241 through 248.

Then, the substrate SUB_1 is transported via the transport unit 220 below the third supply unit 243, and an oxidant is supplied onto the substrate SUB_1. The first precursor adsorbed onto the substrate SUB_1 is oxidized by the supplied oxidant to form a first sub-electrode ET2_1 (e.g., step S406). The oxidant may be oxygen (O₂) or an oxidizing agent. The oxidizing agent may oxidize the precursor (e.g., the first precursor or the second precursor) adsorbed on the substrate SUB_1, and the type of the oxidizing agent is not necessarily limited. The oxidant may be plasma-treated oxygen.

Then, the substrate SUB_1 is transported via the transport unit 220 below the fourth exhaust unit 234, and the oxidant is exhausted and removed through the fourth exhaust unit 234 (e.g., step S407). Then, the substrate SUB_1 is transported via the transport unit 220 below the fourth supply unit 244, and the purge gas is supplied onto the substrate SUB_1 (e.g., step S408). Then, the substrate SUB_1 is transported via the transport unit 220 below the fifth exhaust unit 235, and the supplied purge gas is exhausted through the fifth exhaust unit 235 (e.g., step S409).

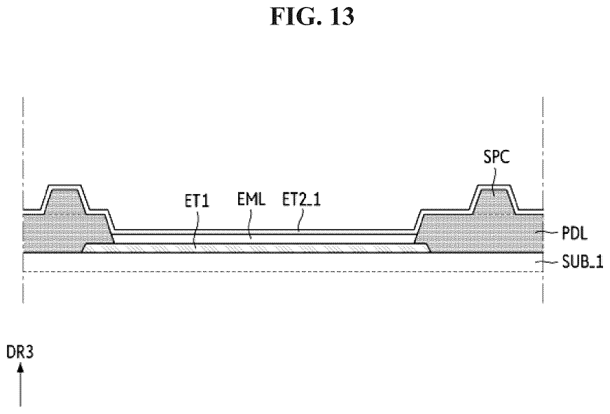

FIG. 13 is a cross-sectional view illustrating the substrate, the first electrode, the pixel-defining layer, the light-emitting layer, the spacers, and a first sub-electrode according to an embodiment of the present disclosure.

Through steps S401 to S409, the first sub-electrode ET2_1 may be formed on the pixel-defining layer PDL, the light-emitting layer EML, and the spacer SPC. By performing steps S401 through S409, the first sub-electrode ET2_1 may be formed with a thickness ranging from 0.5 Å to 10 Å. To increase the thickness of the first sub-electrode ET2_1, steps S401 through S409 may be repeated multiple times until a thickness of the first sub-electrode ET2_1 reaches a target thickness. For example, while performing steps S401 through S409, the substrate SUB_1 may be moved along the first direction DR1 via the transport unit 220. To return to step S401 after step S409, the substrate SUB_1 may be moved in the opposite direction of the first direction DR1 via the transport unit 220.

Then, the substrate SUB_1 is transported via the transport unit 220 below the fifth supply unit 245, and the second precursor is supplied to the first sub-electrode ET2_1 to allow the second precursor to be adsorbed (or adhere to an upper surface of the first sub-electrode ET2_1) (e.g., step S410).

Then, the supply of the second precursor is stopped, and the substrate SUB_1 is transported via the transport unit 220 below the sixth exhaust unit 236. The sixth exhaust unit 236 exhausts and remove the unadsorbed second precursor or residual byproducts remaining on the substrate SUB_1 after adsorption of the second precursor (e.g., step S411).

Then, the substrate SUB_1 is transported via the transport unit 220 below the sixth supply unit 246, and the purge gas is supplied to the substrate SUB_1 on which the second precursor has been adsorbed (e.g., step S412). Then, the substrate SUB_1 is transported via the transport unit 220 below the seventh exhaust unit 237, and the supplied purge gas is exhausted (e.g., step S413).

Then, the substrate SUB_1 is transported via the transport unit 220 below the seventh supply unit 247, and the oxidant is supplied onto the upper surface of the first sub-electrode ET2_1. The second precursor adsorbed on the first sub-electrode ET2_1 is oxidized by the supplied oxidant to form a second sub-electrode ET2_2 (e.g., step S414).

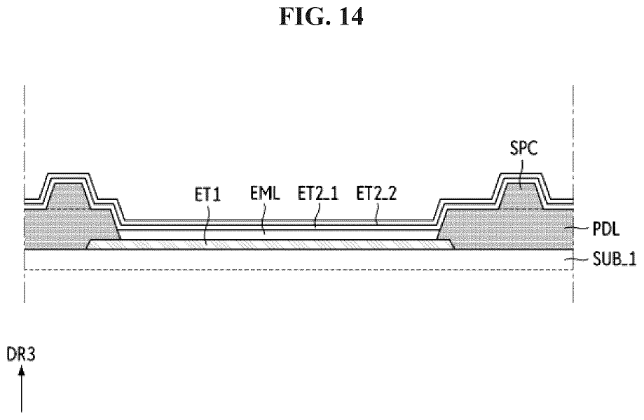

FIG. 14 is a cross-sectional view illustrating the substrate, the first electrode, the pixel-defining layer, the light-emitting layer, the spacers, the first sub-electrode, and a second sub-electrode according to an embodiment of the present disclosure.

Then, the substrate SUB_1 is transported via the transport unit 220 below the eighth exhaust unit 238, and the oxidant is exhausted through the eighth exhaust unit 238 (e.g., step S415). Then, the substrate SUB_1 is transported via the transport unit 220 below the eighth supply unit 248, and the purge gas is supplied onto the upper surface of the second sub-electrode ET2_2 (e.g., step S416). Then, the substrate SUB_1 is transported via the transport unit 220 below the ninth exhaust unit, and the supplied purge gas is exhausted (e.g., step S417).

Through steps S410 to S416, the second sub-electrode ET2_2 may be formed on the first sub-electrode ET2_1. By performing steps S410 through S416, the second sub-electrode ET2_2 may be formed with a thickness ranging from 0.5 Å to 10 Å. To increase the thickness of the second sub-electrode ET2_2, steps S410 through S416 may be repeated multiple times to reach a target thickness of the second sub-electrode ET2_2. In some cases, the thickness of the first sub-electrode ET2_1 may be at least 10 times greater than the thickness of the second sub-electrode ET2_2. In some cases, the number of cycles for forming the second sub-electrode ET2_2 may be less than the number of cycles for forming the first sub-electrode ET2_1.

The following embodiments are intended to describe the present disclosure in further detail, but are merely for illustrative purposes and should not be construed as limiting the scope of the present disclosure.

### 1. Electrode Fabrication

### 1) Embodiment 1

Using DADI as a precursor, an embodiment of the present disclosure forms an indium oxide (In₂O₃) layer as a 2 nm-thick electrode on a substrate using spatial ALD.

### 2) Embodiment 2

Using DEZ as a precursor, an embodiment of the present disclosure forms a ZnO layer as a 2 nm-thick electrode on a substrate using spatial ALD.

### 3) Embodiment 3

Using DADI as a first precursor, an embodiment of the present disclosure forms an In₂O₃ layer having a thickness of 20 nm on a substrate using spatial ALD.

Thereafter, using DEZ as a second precursor, the embodiment of the present disclosure forms a ZnO layer as a 2 nm-thick electrode on the indium oxide layer using spatial ALD.

### 4) Embodiment 4

An embodiment of the present disclosure forms an electrode in the same manner as in Embodiment 3, however, the In₂O₃ layer has a thickness of 40 nm.

### 5) Embodiment 5

An embodiment of the present disclosure forms an electrode in the same manner as in Embodiment 3, however, the In₂O₃ layer has a thickness of 60 nm.

### 6) Embodiment 6

Using DADI as a first precursor and DEZ as a second precursor, an embodiment of the present disclosure forms In₂O₃ and ZnO were alternately deposited on a substrate using spatial ALD to form a multilayered electrode structure.

### Evaluation

### 1. Crystallinity

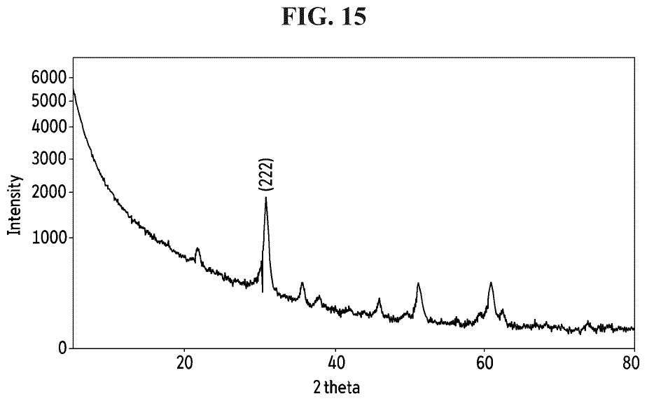

FIG. 15 is an XPS graph based on a first electrode fabrication embodiment. As shown in FIG. 15, the indium oxide layer formed by spatial ALD has the (222) crystal orientation.

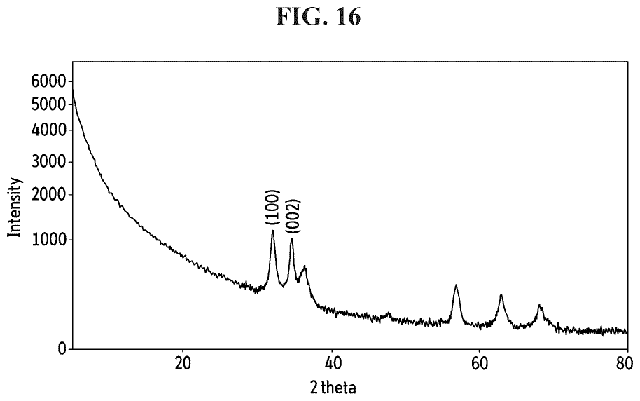

FIG. 16 is an XPS graph based on a second electrode fabrication embodiment. As shown in FIG. 16, the zinc oxide layer formed by spatial ALD has the (100) and (002) crystal orientations.

### 2. Resistance

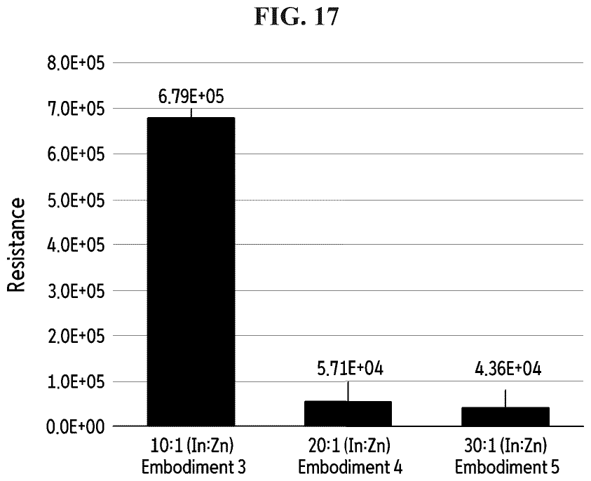

FIG. 17 is a graph showing the resistances of the electrodes fabricated based on the third electrode fabrication embodiment through the fifth electrode fabrication embodiment.

As shown in FIG. 17, the resistance of each electrode decreases as the amount of In₂O₃ increases. Accordingly, to achieve an electrode with a lower resistance value, a larger thickness of In₂O₃ can be deposited on to the electrode with respect to the thickness of the ZnO layer.

### 3. Electrode Thickness

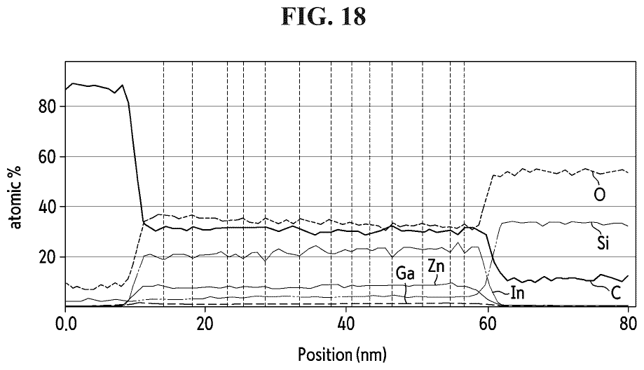

FIG. 18 is an XPS depth profile graph based on a stacked fabrication embodiment (e.g., the sixth electrode fabrication embodiment).

As shown in FIG. 18, the regions where the atomic percentage (at %) of In decreases and that of Zn increases are indicated with dotted lines. These regions correspond to the thicknesses of respective zinc oxide layers formed. When forming layers of an electrode using spatial ALD, the thickness of each layer can range from 0.5 Å to 10 Å, which is too small to be distinguishable via an electron microscope such as an SEM or TEM. As shown in FIG. 18, the thickness of the electrode can be verified using its XPS depth profile.

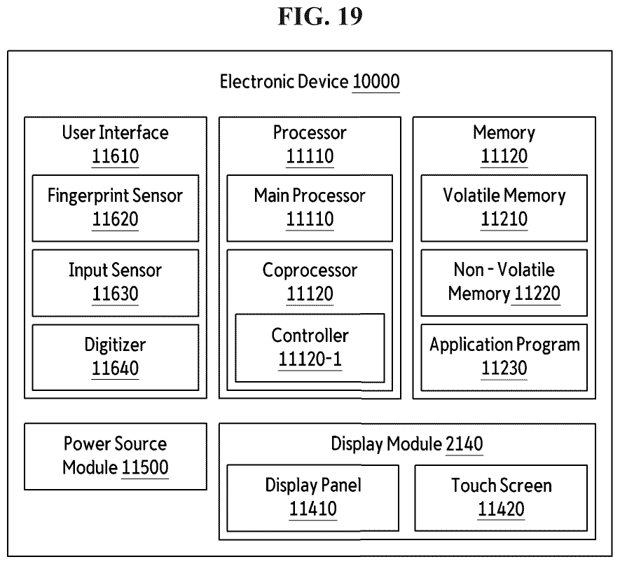

FIG. 19 is a diagram illustrating an electronic device according to an embodiment of the present invention. Referring to FIG. 19, the electronic device 10000 according to one embodiment of the present invention may output various information (e.g., images, text, music, etc.) through a display module 11400, which, for example, may correspond to the display device 1 shown in FIG. 1. When a processor 11100 executes an application stored in a memory 11200, the display module 11400 may provide application information to a user through a display panel 11410. Display panel 11410 may be an example of, or includes aspects of, the display panel 100 described with reference to FIG. 1.

In some embodiments, the electronic device 10000 may be configured as a smartphone, camera, smart TV, monitor, smartwatch, tablet, automotive display, or AR/VR headset. For example, the electronic device 10000 may be a smartphone including a touch-sensitive display area DA for interaction and a non-display area NDA including sensors and circuits for enhanced functionality. For example, the electronic device 10000 may be a television or monitor including a large display area DA for high-resolution video playback and a non-display area NDA incorporating driving circuits or connectivity modules for external inputs. For example, the electronic device 10000 may be a smartwatch including a display area DA optimized for compact and high-clarity visuals and a non-display area NDA integrating biometric sensors for health monitoring. In some cases, the electronic device 10000 be an AR/VR headset.

In some embodiments, memory 11200 may store information such as software codes for operating an application program 11230. The application program 11230 may include a software designed to execute specific tasks or provide functionality to a user. The application program 11230 may operate under the control of the processor 11100 and utilizes data stored in the memory 11200 to deliver a wide range of features, such as productivity tools, multimedia streaming and playback, file or mail deliveries or communication services. The application program 11230 interacts seamlessly with the user interface 11610 or touch screen 11420, allowing a user to launch, navigate, and utilize the program through user inputs such as touch, tap, gesture, or voice interaction.

Upon user selection of an application via touch screen 11420 or user interface 11610, the processor 11100 may execute the application program 11230 corresponding to the selected application retrieved from the memory 11200 to perform functionalities of the application. For example, when a user selects a camera application by tapping the icon (or a camera application icon) presented on the display panel 11410, the processor 11100 activates a camera module. The processor 11100 may transmit image data corresponding to a captured image acquired through the camera module to the display module 11400. The display module 11400 may display an image corresponding to the captured image through the display panel 11410.

As another example, when a user wishes to make a phone call, the user taps the telephone icon displayed on the display module 11400, the processor 11100 may execute a phone application program stored in the memory 11200. A telephone keypad may be presented on the display panel 11410 for the user to enter a phone number to call.

As another example, the display module 11400 may be integrated into an electronic device 10000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 11100 may include a main processor 11110 and an auxiliary or coprocessor 11120. The main processor 11110 may include a central processing unit (CPU). The main processor 11110 may further include one or more of a graphics processing unit (GPU), a communication processor (CP), and an image signal processor (ISP).

The coprocessor 11120 may include a controller 11120-1. The controller 11120-1 may include an interface conversion circuit and a timing control circuit. The controller 11120-1 may receive an image signal from the main processor 11110, convert the data format of the image signal to match the interface specifications with the display module 11400, and output image data. The controller 11120-1 may output various control signals to drive the display module 11400. For example, the controller 11120-1 may drive the display module 11400 to display the icon on the display screen suitable for selection by a user to cause execution of an application program 11230.

The memory 11200 may store one or more application programs 11230 and various data used by at least one component (for example, the processor 11100 or the user interface 11610) of the electronic device 10000 and input data or output data for commands related thereto. For example, a camera application program, a GPS application program, an augmented reality and virtual reality application program, and other application programs that can be executed by the processor 11100 upon selection of corresponding icons presented on the display screen (or display panel 11410) via the touch screen 11420 or user interface 11610 by the user. In addition, various setting data corresponding to user settings may be stored in the memory 11200. The memory 11200 may include volatile memory 11210 and non-volatile memory 11220.

The display module 11400 may output visual information (images) to the user. The display module 11400 may include the display panel 11410, a gate driver, the source driver, a voltage generation circuit, and a touch screen 11420. The display module 11400 may further include a window, a chassis, and a bracket to protect the display panel 11410. The display module 1140 may include at least a part of the configuration of the display device shown in FIG. 1.

The user interface 11610 serves as the interaction medium between a user and the electronic device 10000. The user interface 11610 may detect an input by a part (e.g., finger) of a user's body or an input by a pen or a mouse, and generate an electric signal or data value corresponding to the input. The user interface 11610 includes the fingerprint sensor 11620, the input sensor 11630, and a digitizer 11640.

The fingerprint sensor 11620 may sense a fingerprint for biometric recognition of the user and may also measure one or more biological signals such as blood pressure, moisture, or body mass.

The input sensor 11630 may sense user interactions including touch, tap, gesture, motion, spoken command, and eye movement. The input sensor 11630 includes optical sensors for image capture, eye tracking, or motion and gesture detection. Optical sensors may be infrared or semiconductor photodetectors. The input sensor 11630 includes audio and acoustic sensors, which may be MEMS microphones for voice recognition or sound-based interaction. The audio and acoustic sensors can be installed as part of the user interface 11610 or embedded in the display panel 11410.

The digitizer 11640 may generate a data value corresponding to coordinate information of input by a pen or a mouse to control movement of an onscreen cursor. The digitizer 11640 may generate the amount of change in electromagnetic due to the input as the data value. The digitizer may detect an input by a passive pen or transmit and receive data with an active pen or a remote.

At least one of the fingerprint sensor 11620, the input sensor 11630, or the digitizer 11640 may be implemented as a sensor layer formed on the top layer of the display panel 11410 through a continuous process with a process of forming elements (for example, the light emitting element, the transistor, and the like) included in the display panel 11410.

In addition, the user interface 11610 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 11420 includes touch sensors embedded in semiconductor layers of the display panel 11410 to sense pressure applied to the top layer (screen) of the display panel 11410. The touch sensors can be a capacitive or a resistive type. The touch screen 11420 may serve as the primary interface for the user to select and navigate applications, control, and interact with the electronic device 10000.

The display panel 11410 (or display) may include a liquid crystal display panel, an organic light emitting display panel, or an inorganic light emitting display panel, and the type of the display panel 11410 is not particularly limited. The display panel 11410 may be of a rigid type or a flexible type that can be rolled or folded. The display module 11400 may further include a supporter, bracket, heat dissipation member, and the like that support the display panel 11410. The display panel 11410 may include the display unit shown in FIG. 1.

The power source module 11500 may supply power to the components of the electronic device 10000. The power source module 11500 may include a battery that charges the power source voltage. The battery may include a non-rechargeable primary battery or a rechargeable secondary battery or fuel cell. The power source module 11500 may include a power management integrated circuit (PMIC). The PMIC may supply optimized power source to each of the components described above including the display module 11400.

Although the embodiments of the present invention have been described with reference to the attached drawings, those skilled in the art will understand that the present invention can be implemented in other specific forms without changing the technical idea or essential features of the present invention. Therefore, it should be understood that the embodiments described above are exemplary in all respects and not necessarily restrictive.

What is claimed is:

1. A method for manufacturing a display device, comprising:
forming a first electrode on a substrate;
forming a pixel-defining layer on the substrate, wherein the pixel-defining layer includes an opening that exposes at least a portion of an upper surface of the first electrode;
forming a light-emitting layer on the upper surface of the first electrode; and
forming a second electrode on the light-emitting layer and the pixel-defining layer using spatial atomic layer deposition,
wherein the second electrode is formed to include a first sub-electrode and a second sub-electrode disposed on the first sub-electrode.

2. The method of claim 1, wherein:
the first sub-electrode and the second sub-electrode comprise different materials, and wherein the first sub-electrode and the second sub-electrode are formed in a single deposition chamber.

3. The method of claim 2, wherein forming the second electrode comprises:
supplying a first precursor into the deposition chamber to adsorb the first precursor onto the light-emitting layer and the pixel-defining layer;
exhausting an excess of the first precursor in the deposition chamber;
supplying a purge gas onto the adsorbed first precursor in the deposition chamber;
forming the first sub-electrode by supplying an oxidant to oxidize the adsorbed first precursor in the deposition chamber;
supplying a second precursor into the deposition chamber to adsorb the second precursor onto the first sub-electrode;
exhausting an excess of the second precursor in the deposition chamber;
supplying the purge gas onto the adsorbed second precursor in the deposition chamber;
forming the second sub-electrode by supplying the oxidant to oxidize the adsorbed second precursor; and
exhausting an excess of the oxidant.

4. The method of claim 3, wherein:
the first precursor and the second precursor include at least one of indium, zinc, tin, aluminum, or gallium.

5. The method of claim 1, wherein:
the second electrode includes at least one of indium oxide, zinc oxide, tin oxide, aluminum oxide, or gallium oxide.

6. The method of claim 1, wherein:
a thickness of the second electrode ranges from 10 Å to 1,000 Å.

7. The method of claim 1, further comprising:
forming a spacer on the pixel-defining layer.

8. The method of claim 1, wherein:
a first thickness of the second electrode measured from an upper surface of the pixel-defining layer is within a range of 90% to 100% of a second thickness of the second electrode measured from a side surfaces of the pixel-defining layer.

9. The method of claim 1, wherein:
a ratio of a thickness of the first sub-electrode to a thickness of the second sub-electrode is greater than or equal to 10:1.

10. The method of claim 1, wherein forming the second electrode further comprises:
forming a third sub-electrode on the second sub-electrode; and
forming a fourth sub-electrode on the third sub-electrode.

11. The method of claim 10, wherein the first sub-electrode, second sub-electrode, third sub-electrode, or fourth sub-electrode has crystallinity in case that having a thickness of 20 Å or greater.

12. The method of claim 11, wherein the crystallinity corresponds to at least one of the (222), (100), or (002) crystal orientation.

13. A display device, comprising:
a substrate;
a first electrode disposed on the substrate;
a pixel-defining layer disposed on the first electrode, wherein the pixel-defining layer includes an opening that exposes at least a portion of an upper surface of the first electrode;
a light-emitting layer disposed on the upper surface of the first electrode; and
a second electrode disposed on the light-emitting layer and the pixel-defining layer,
wherein the second electrode includes a first sub-electrode and a second sub-electrode disposed on the first sub-electrode,
wherein a thickness of the second electrode ranges from 10 Å to 1,000 Å, and
wherein a ratio of a thickness of the first sub-electrode to a thickness of the second sub-electrode is greater than or equal to 10:1.

14. The display device of claim 13, wherein the second electrode further comprises:
a third sub-electrode disposed on the second sub-electrode; and
a fourth sub-electrode disposed on the third sub-electrode.

15. The display device of claim 13, wherein:
a first thickness of the second electrode measured from an upper surface of the pixel-defining layer is within a range of 90% to 100% of a second thickness of the second electrode measured from a side surface of the pixel-defining layer.

16. The display device of claim 13, wherein:
the second electrode includes at least one of indium oxide, zinc oxide, tin oxide, aluminum oxide, or gallium oxide.

17. The display device of claim 14, wherein the first sub-electrode, second sub-electrode, third sub-electrode, or fourth sub-electrode has crystallinity in case that having a thickness of 20 Å or greater.

18. The display device of claim 17, wherein the crystallinity corresponds to at least one of the (222), (100), or (002) crystal orientation.

19. An electronic device, comprising:
a processor;
a memory having stored application programs for execution by the processor;
a display device including a display panel, wherein the display panel comprises:
a first electrode disposed on a substrate;
a pixel-defining layer disposed on the first electrode, wherein the pixel-defining layer includes an opening that exposes at least a portion of an upper surface of the first electrode;
a light-emitting layer disposed on the upper surface of the first electrode; and
a second electrode disposed on the light-emitting layer and the pixel-defining layer,
wherein the second electrode includes a first sub-electrode and a second sub-electrode disposed on the first sub-electrode,
wherein a thickness of the second electrode ranges from 10 Å to 1,000 Å, and
wherein a ratio of a thickness of the first sub-electrode to a thickness of the second sub-electrode is greater than or equal to 10:1.

20. The electronic device of claim 19, wherein:
the first sub-electrode and the second sub-electrode include different materials.
